(19) United States
(12) Patent Application Publication
(10) Pub. No.: US 2022/0232734 A1
(43) Pub. Date: Jul. 21, 2022

(54) SYSTEMS AND METHODS FOR IMMERSION COOLING WITH AN AIR-COOLED CONDENSER

(71) Applicant: Microsoft Technology Licensing, LLC, Redmond, WA (US)

(72) Inventors: Bharath RAMAKRISHNAN, Bellevue, WA (US); Eric C. PETERSON, Woodinville, WA (US); Husam Atallah ALISSA, Redmond, WA (US)

(21) Appl. No.: 17/150,630

(22) Filed: Jan. 15, 2021

(51) Int. Cl. H05K 7/20

(52) U.S. Cl. CPC H05K 7/20318; H05K 7/20381; H05K 7/203; H05K 7/20209

(57) ABSTRACT

A thermal management system includes an immersion tank, a cooling fluid, and an air-cooled condenser. The immersion tank devices an immersion chamber, and the cooling fluid is at least partially located in the immersion chamber. The air-cooled condenser is in fluid communication with the immersion chamber to cool the cooling fluid.

### BACKGROUND

### Background and Relevant Art

Computing devices can generate a large amount of heat during use. The computing components can be susceptible to damage from the heat and commonly require cooling systems to maintain the component temperatures in a safe range during heavy processing or usage loads. Liquid cooling can effectively cool components as liquid cooling fluids have more thermal mass than air or gas cooling. The liquid cooling fluid can be maintained at a lower temperature by allowing vaporized fluid to rise out of the liquid. The vapor in the cooling liquid can adversely affect the cooling performance of the cooling fluid. The vapor can be condensed and returned to the boiler tank.

### BRIEF SUMMARY

In some embodiments, a thermal management system includes an immersion tank, a cooling fluid, and an air-cooled condenser. The immersion tank devices an immersion chamber, and the cooling fluid is at least partially located in the immersion chamber. The air-cooled condenser is in fluid communication with the immersion chamber to cool the cooling fluid.

In some embodiments, a thermal management system includes an immersion tank, a cooling fluid, an air-cooled condenser, a vapor return line and a liquid return line each connecting the immersion tank to the air-cooled condenser, and a condensate reservoir. The immersion tank devices an immersion chamber, and the cooling fluid is at least partially located in the immersion chamber. The air-cooled condenser is in fluid communication with the immersion chamber to cool the cooling fluid. The vapor return line conveys a vapor phase of the cooling fluid to the air-cooled condenser, and the liquid return line conveys a liquid phase of the cooling fluid from the air-cooled condenser back to the immersion chamber. The condensate reservoir is positioned in the liquid return line and configured to store at least a portion of the liquid phase of the cooling fluid.

In some embodiments, a thermal management system includes an immersion tank, a cooling fluid, an air-cooled condenser, a vapor return line and a liquid return line each connecting the immersion tank to the air-cooled condenser, and a condensate reservoir. The immersion tank devices an immersion chamber, and the cooling fluid is at least partially located in the immersion chamber. The air-cooled condenser is in fluid communication with the immersion chamber to cool the cooling fluid, and the air-cooled condenser includes a heat exchanger and a fan to move air past the heat exchanger. The vapor return line conveys a vapor phase of the cooling fluid to the air-cooled condenser, and the liquid return line conveys a liquid phase of the cooling fluid from the air-cooled condenser back to the immersion chamber. The condensate reservoir is positioned in the liquid return line and configured to store at least a portion of the liquid phase of the cooling fluid.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a side schematic representation of an immersion cooling system, according to at least one embodiment of the present disclosure;

FIG. 2 is a side schematic representation of an immersion cooling system with an external condenser, according to at least one embodiment of the present disclosure;

FIG. 3 is a schematic view of cooling fluid transport through an air-cooled immersion cooling system, according to at least one embodiment of the present disclosure;

FIG. 4 is a side cross-sectional view of a side-condenser immersion cooling system, according to at least one embodiment of the present disclosure;

FIG. 5 is a side cross-sectional view of a top-condenser immersion cooling system, according to at least one embodiment of the present disclosure;

FIG. 6 is a perspective exploded view of an immersion cooling system with a plurality of heat exchangers, according to at least one embodiment of the present disclosure; and

FIG. 7 is a sequence of stacking heat pipe heat-exchangers, according to at least one embodiment of the present disclosure.

### DETAILED DESCRIPTION

The present disclosure relates generally to systems and methods for thermal management of electronic devices or other heat-generating components Immersion chambers surround the heat-generating components in a liquid cooling fluid, which conducts heat from the heat-generating components to cool the heat-generating components. As the cooling fluid absorbs heat from the heat-generating components, the temperature of the cooling fluid increases and the cooling fluid may vaporize, introducing vapor into the liquid of the cooling fluid.

In large-scale computing centers, such as cloud-computing centers, data processing centers, data storage centers, or other computing facilities, immersion cooling systems provide an efficient method of thermal management for many computing components under a variety of operating loads. In some embodiments, an immersion cooling system includes a cooling fluid in an immersion tank and a condenser to extract heat from the vapor of the cooling fluid. The condenser then condenses the vapor phase of the cooling fluid into a liquid phase and returns the liquid cooling fluid to the immersion chamber of the immersion tank. In smaller distributed data centers, a low maintenance option for high efficiency immersion cooling is beneficial. An air-cooled immersion cooling system can eliminate potential failure points and maintenance requirements associated with liquid-cooled or water-cooled immersion cooling systems.

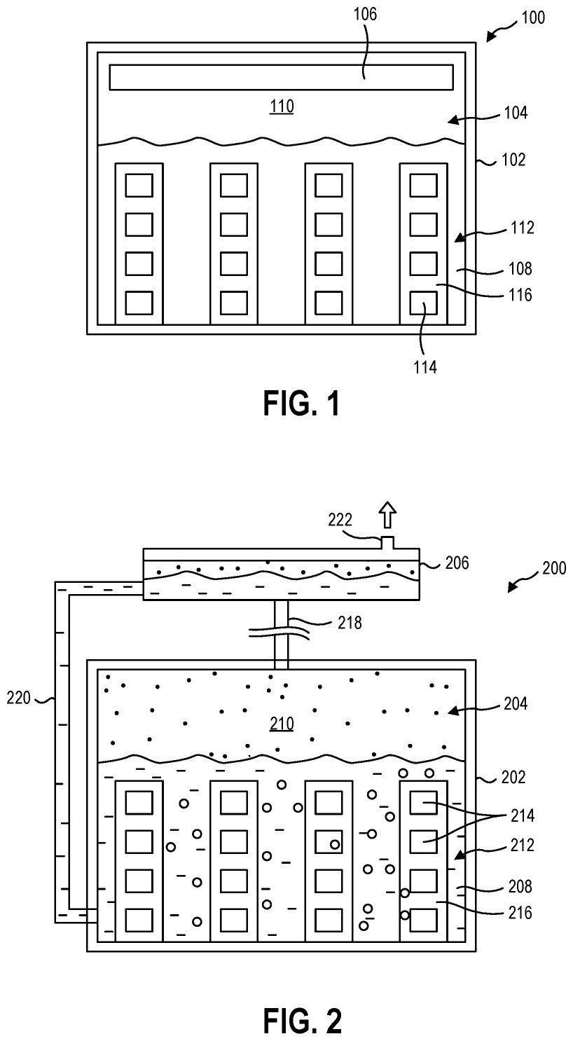

A conventional immersion cooling system 100, shown in FIG. 1, includes an immersion tank 102 containing an immersion chamber 104 and a condenser 106 in the immersion chamber 104. The immersion chamber 104 contains a cooling fluid that has a liquid cooling fluid 108 and a vapor cooling fluid 110 portion. The liquid cooling fluid 108 creates an immersion bath 112 in which a plurality of heat-generating components 114 are positioned to heat the liquid cooling fluid 108.

Referring now to FIG. 2, an immersion cooling system 200 according to the present disclosure includes an immersion tank 202 defining an immersion chamber 204 with a cooling fluid positioned therein. The cooling fluid transitions between a liquid cooling fluid 208 phase and a vapor cooling fluid 210 phase to remove heat from hot or heat-generating components 214 in the immersion chamber 204. The liquid cooling fluid 208 more efficiency receives heat from the heat-generating components 214 and, upon transition to the vapor cooling fluid 210, the vapor cooling fluid 210 can be removed from the immersion tank 202, cooled and condensed by the condenser 206 to extract the heat from the cooling fluid, and the liquid cooling fluid 208 can be returned to the liquid immersion bath 212.

In some embodiments, the immersion bath 212 of the liquid cooling fluid 208 has a plurality of heat-generating components 214 positioned in the liquid cooling fluid 208. The liquid cooling fluid 208 surrounds at least a portion of the heat-generating components 214 and other objects or parts attached to the heat-generating components 214. In some embodiments, the heat-generating components 214 are positioned in the liquid cooling fluid 208 on one or more supports 216. The support 216 may support one or more heat-generating components 214 in the liquid cooling fluid 208 and allow the cooling fluid to move around the heat-generating components 214. In some embodiments, the support 216 is thermally conductive to conduct heat from the heat-generating components 214. The support(s) 216 may increase the effective surface area from which the liquid cooling fluid 208 may remove heat through convective cooling.

In some embodiments, the heat-generating components 214 include computer components or power supplies. In some embodiments, the heat-generating components 214 include computer devices, such as individual personal computer or server blade computers. In some embodiments, one or more of the heat-generating components 214 includes a heat sink or other device attached to the heat-generating component 214 to conduct away thermal energy and effectively increase the surface area of the heat-generating component 214.

As described, conversion of the liquid cooling fluid 208 to a vapor phase requires the input of thermal energy to overcome the latent heat of vaporization and may be an effective mechanism to increase the thermal capacity of the cooling fluid and remove heat from the heat-generating components. Because the vapor cooling fluid 210 rises in the liquid cooling fluid 208, the vapor cooling fluid 210 can be extracted from the immersion chamber 204 in an upper vapor region of the chamber. A condenser 206 cools part of the vapor cooling fluid 210 back into a liquid cooling fluid 208, removing thermal energy from the system and reintroducing the cooling fluid into the immersion bath 212 of the liquid cooling fluid 208. The condenser 206 radiates or otherwise dumps the thermal energy from the cooling fluid into the ambient environment or into a conduit to carry the thermal energy away from the cooling system.

In conventional immersion cooling systems, a liquid-cooled condenser is integrated into the immersion tank and/or the chamber to efficiency remove the thermal energy from the cooling fluid. In some embodiments according to the present disclosure, an immersion cooling system 200 for thermal management of computing devices allows at least one immersion tank 202 and/or chamber 204 to be connected to and in fluid communication with an external condenser 206. In some embodiments, an immersion cooling system includes a vapor return line 218 that connects the immersion tank 202 to the condenser 206 and allows vapor cooling fluid 210 to enter the condenser 206 from the immersion tank 202 and/or chamber 204 and a liquid return line 220 that connects the immersion tank 202 to the condenser 206 and allows liquid cooling fluid 208 to return to the immersion tank 202 and/or chamber 204.

The vapor return line 218 may be colder than the boiling temperature of the cooling fluid. In some embodiments, a portion of the vapor cooling fluid condenses in the vapor return line 218. The vapor return line 218 can, in some embodiments, be oriented at an angle such that the vapor return line 218 is non-perpendicular to the direction of gravity. The condensed cooling fluid can then drain either back to the immersion tank 202 or forward to the condenser 206 depending on the direction of the vapor return line 218 slope. In some embodiments, the vapor return line 218 includes a liquid collection line or valve, like a bleeder valve, that allows the collection and/or return of the condensed cooling fluid to the immersion tank 202 or condenser 206.

In some embodiments, the liquid cooling fluid 208 receives heat in a cooling volume of cooling fluid immediately surrounding the heat-generating components 214. The cooling volume is the region of the cooling fluid (including both liquid and vapor phases) that is immediately surrounding the heat-generating components 214 and is responsible for the convective cooling of the heat-generating components 214. In some embodiments, the cooling volume is the volume of cooling fluid within 5 millimeters (mm) of the heat-generating components 214. In some embodiments, the cooling volume is the volume of cooling fluid within 5 mm of the vertical stacks (supports 216 and heat-generating components 214). In some embodiments, the cooling volume is defined by a vertical cylinder around each of the vertical stacks where no portion of the cylinder is outside 5 mm of the heat-generating components.

The cooling fluid has a boiling temperature below a critical temperature at which the heat-generating components experience thermal damage. For example, the heat-generating components may be computing components that experience damage above 100° Celsius (C). In some embodiments, the boiling temperature of the cooling fluid is less than a critical temperature of the heat-generating components. In some embodiments, the boiling temperature of the cooling fluid is less about 90° C. In some embodiments, the boiling temperature of the cooling fluid is less about 80° C. In some embodiments, the boiling temperature of the cooling fluid is less about 70° C. In some embodiments, the boiling temperature of the cooling fluid is less about 60° C. In some embodiments, the boiling temperature of the cooling fluid is at least about 35° C. In some embodiments, the cooling fluid includes water. In some embodiments, the cooling fluid includes glycol. In some embodiments, the cooling fluid includes a combination of water and glycol. In some embodiments, the cooling fluid is an aqueous solution. In some embodiments, the cooling fluid is an electronic liquid, such as FC-72 available from 3M, or similar non-conductive fluids. In some embodiments, the heat-generating components, supports, or other elements of the immersion cooling system positioned in the cooling fluid have nucleation sites on a surface thereof that promote the nucleation of vapor bubbles of the cooling fluid at or below the boiling temperature of the cooling fluid.

In some embodiments, an immersion cooling system 200 according to the present disclosure includes an air-cooled condenser 206. A liquid-cooled condenser can introduce couplings and/or conduits that are potential failure points. Leaks in the condenser can adversely affect the reliability of the condenser, risking the cooling efficiency of the immersion cooling system 200. In some examples, a liquid-cooled condenser that is water-cooled can introduce water into the cooling fluid of the immersion cooling system 200, increasing the boiling temperature of the cooling fluid. Changes to the boiling temperature of the cooling fluid can result in the heat-generating components achieving higher-than-intended temperatures, which may risk damage to the heat-generating components.

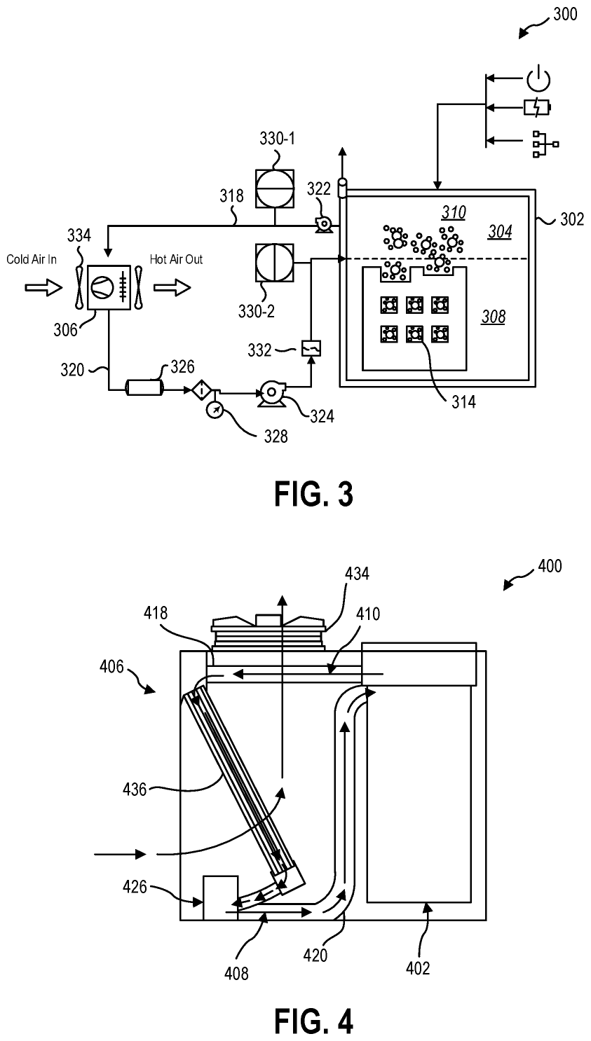

FIG. 3 is a schematic diagram of an immersion cooling system 300 according to some embodiments of the present disclosure. The immersion tank 302 defines an immersion chamber 304 connected to an air-cooled condenser 306. The air-cooled condenser 306 is connected to the immersion chamber 304 by a vapor return line 318 and a liquid return line 320. In some embodiments, a vapor pump 322 is positioned in-line with the vapor return line 318. In some embodiments, a liquid pump 324 is positioned in-line with the liquid return line 320. In some embodiments, the immersion cooling system includes only one of the vapor pump 322 or liquid pump 324. For example, in a system with only a liquid pump 324, the condensation of the vapor cooling fluid 310 in a liquid cooling fluid 308 in the condenser 306 creates a low pressure region at or near the condenser 306, which draws vapor cooling fluid 310 through the vapor return line 318 from the immersion chamber 304. In another example, in a system with only a vapor pump 322 can create a region of high pressure at or near the condenser 306 that forces liquid cooling fluid 308 through the liquid return line 320.

In some embodiments, the liquid return line includes a condensate reservoir 326, which allows the liquid cooling fluid 308 condensed in the condenser 306 to be stored. The liquid cooling fluid 308 can be selectively released to the immersion chamber 304 via a valve in or after the condensate reservoir 326 in the liquid return line 320.

When working on the immersion cooling system 300, such as installing, uninstalling, or repairing the immersion cooling system, as well as installing, uninstalling, or repairing heat-generating components 314 in the immersion cooling system 300, non-condensable gases may be introduced into the system. It should be understood that a non-condensable gas, as described herein, includes any gaseous element or compound that is not condensable into a liquid phase by the condenser 306. For example, while the cooling fluid is condensable by the condenser during normal operational conditions, binary oxygen (O₂) is not. Conversely, while O₂ is condensable into a liquid phase at extremely low temperatures, such condensation is beyond the capability or intent of condensers 306 according to the present disclosure, and O₂ is an example of a non-condensable gas. Other common non-condensable gases that may be introduced into the system include nitrogen and carbon dioxide. Non-condensable gases do not experience a phase change as they move through the immersion cooling system 300 cycle. Therefore, the non-condensable gases do not allow for the same level of thermal energy transport as the cooling fluid moving between liquid and vapor phases, and the non-condensable gases can compromise the thermal management capacity of the immersion cooling system 300.

Non-condensable gases will pass through the condenser 306 and may enter the liquid return line 320. Before the non-condensable gases can enter the immersion tank 302 through the liquid return line 320, the non-condensable gases may be filtered from the liquid return line 320 and vented through a vent 328. In some embodiments, the non-condensable gases are vented to atmosphere. In some embodiments, the non-condensable gases may be vented to another pipe or conduit to be collected. In some embodiments, the non-condensable gases vent 328 is located before the condensate reservoir 326. In some embodiments, the non-condensable gases vent 328 is located after the condensate reservoir 326. In some embodiments, the non-condensable gases vent 328 is integrated into the condensate reservoir 326 allowing the non-condensable gases to be vented from the condensate reservoir 326. For example, the condensate reservoir 326 may have an outlet located at or near a bottom of the condensate reservoir that allow liquid cooling fluid 308 to flow into the liquid return line 320, and the condensate reservoir 326 may have a non-condensable gases vent 328 located at or near a top of the condensate reservoir 326 such that only gaseous material can exit through the vent. The density of the liquid condensate (e.g., the liquid cooling fluid 308) will separate the material in the condensate reservoir 326 and allow the liquid cooling fluid 308 to continue returning to the immersion tank 302.

Immersion cooling systems according to the present disclosure may include a variety of sensors to monitor the flow rate, pressure, temperature, density, or other properties and/or parameters of the immersion cooling system and/or cooling fluid. For example, sensors may be positioned at or in the immersion tank, the vapor return line, the liquid return line, the condenser, the condensate reservoir, other components of the immersion cooling system, or combinations thereof. In some embodiments, the immersion cooling system includes a plurality of at least one type of sensor to monitor changes to that property within the immersion cooling system. For example, an immersion cooling system according to the present disclosure may include temperature sensors at a plurality of location in or on the immersion cooling system to monitor temperature gradients and cooling efficiency in the immersion cooling system.

In embodiments of immersion cooling systems such as that described in relation to FIG. 3, an immersion cooling system 300 includes temperature and pressure sensors 330-1, 330-2 that measure a change in temperature and pressure between the vapor return line 318 and the liquid return line 320. The immersion cooling system 300 can use a first temperature and pressure sensor 330-1 positioned on the vapor return line 318 proximate the immersion tank 302 to measure the temperature and pressure of the heated vapor cooling fluid 310 exiting the immersion tank 302. The immersion cooling system 300 can use a second temperature and pressure sensor 330-2 positioned on the liquid return line 320 proximate the immersion tank 302 to measure the temperature and pressure of the liquid cooling fluid 308 returning to the immersion tank 302. The differences between the two temperature and pressure sensors 330-1, 330-2 can provide a gradient that indicates the cooling efficiency of the condenser 306.

In some embodiments, an immersion cooling system 300 includes one or more flow rate sensors 332. The flow rate sensors 332 can monitor the rate of transport of the cooling fluid through the vapor return line 318 and/or the liquid return line 320. It should be understood that the flow rate of the liquid cooling fluid 308 in the liquid return line 320 is lower than the flow rate of the vapor cooling fluid 310 in the vapor return line 318 when the immersion cooling system 300 in a steady state, as the vapor cooling fluid 310 is less dense than the liquid cooling fluid 308. In some embodiments, the immersion cooling system 300 includes a flow rate sensor 332 on the liquid return line 320, and flow rates measured by the flow rate sensor 332 may be used to adjust a valve on the condensate reservoir 326 and change the flow rate.

Some embodiments of a condenser 306 according to the present embodiment are air cooled condensers that dissipate heat from the cooling fluid to the surrounding air. An air-cooled condenser is lower maintenance and more reliable than a liquid-cooled condenser. The air-cooled condenser includes a thermally conductive material that transfers heat from the cooling fluid to air passing over a heat exchanger of the condenser. In some embodiments, the heat exchanger includes one or more features or structures to increase surface area of the heat exchanger. For example, the heat exchanger may include a plurality of fins or columns that receive heat from the cooling fluid and conduct the heat to the air through convective heat transfer. The fins may be positioned substantially parallel to one another to allow airflow through the spaces between the fins. In some examples, the heat exchanger may include a heat spreader that increases the surface area exposed to the air. In some examples, the heat spreader is integrated with the fins or columns. In some examples, the heat exchanger includes a vapor chamber or heat pipe(s) to efficiently move heat across a large surface area.

In some embodiments, a condenser 306 includes active cooling, such as a fan 334 or blower to force air past the heat exchanger. The fan 334 may be an axial fan, a centrifugal blower, or a mixed flow fan. In some embodiments, the fan 334 is an electric fan powered by an external power source. In some embodiments, the fan 334 is a thermoelectric fan that generates power from a temperature gradient, such as between the hot vapor cooling fluid 310 and the surrounding air. A thermoelectric fan may flow air faster when the temperature gradient is larger, providing an adaptive and self-powering fan.

The condenser 306 may include a plurality of fans 334 to provide redundancy to the condenser 306. In some embodiments, at least two of the plurality of fans 334 are the same, such that the second fan can replace the functionality and provide a backup to the first fan. In some embodiments, the condenser includes at least two different fans 334 (e.g., an axial fan and a centrifugal blower or axial fans of different sizes) that provide efficient airflow at different flow rates. The condenser can operate one or both of the two different fans 334 based on the properties measured by the sensors (such as the temperature and pressure sensors 330-1, 330-2 and the flow rate sensor 332).

Immersion cooling systems according to the present disclosure may include condensers positioned at various locations relative to the immersion tank. In embodiments with fans to move air over the heat exchanger, the condenser may be positioned vertically or horizontally on the top or sides of the immersion tank. For example, an immersion cooling system according to the present disclosure may have an air-cooled condenser positioned on the side of the immersion tank (i.e., positioned side-by-side with the immersion tank relative to the direction of gravity).

FIG. 4 is a side cross-sectional view of an embodiment of a side-condenser immersion cooling system 400. In some embodiments, the condenser 406 is positioned side-by-side with the immersion tank 402. A side-condenser arrangement allows uses the relative density of the vapor cooling fluid 410 and the liquid cooling fluid 408 to move the vapor cooling fluid 410 and liquid cooling fluid 408 through the condenser 406 and through the vapor return line 418 and liquid return line 420. In some embodiments, the vapor return line 418 is positioned at the top or near the top of the immersion tank 402 and provides fluid communication to the top of the condenser 406.

The fan 434 draws air through the condenser 406 and over the heat exchanger 436 to condense the vapor cooling fluid 410 into liquid cooling fluid 408. The condenser 406 may be oriented with a conduit through the heat exchanger 436 having a vertical component (e.g., parallel to a direction of gravity or angled relative to the direction of gravity with a horizontal and a vertical component) such that the cooling fluid will, upon condensation, flow downward through the condenser 406 away from the vapor return line 418 and toward the liquid return line 420 and condensate reservoir 426. While the embodiment illustrated in FIG. 4 draws air in the side of the condenser 406 and exhausts air out the top of the condenser 406 at the fan 434, in other embodiments, the condenser 406 may draw air from the bottom of the condenser 406 and exhaust the air out the top. In some embodiments, a side-condenser immersion cooling system 400 may intake air at a front of the condenser 406 and exhaust the air out a back of the condenser 406. The direction of airflow through the condenser may be selected and/or changed depending on the airflow through the surrounding environment.

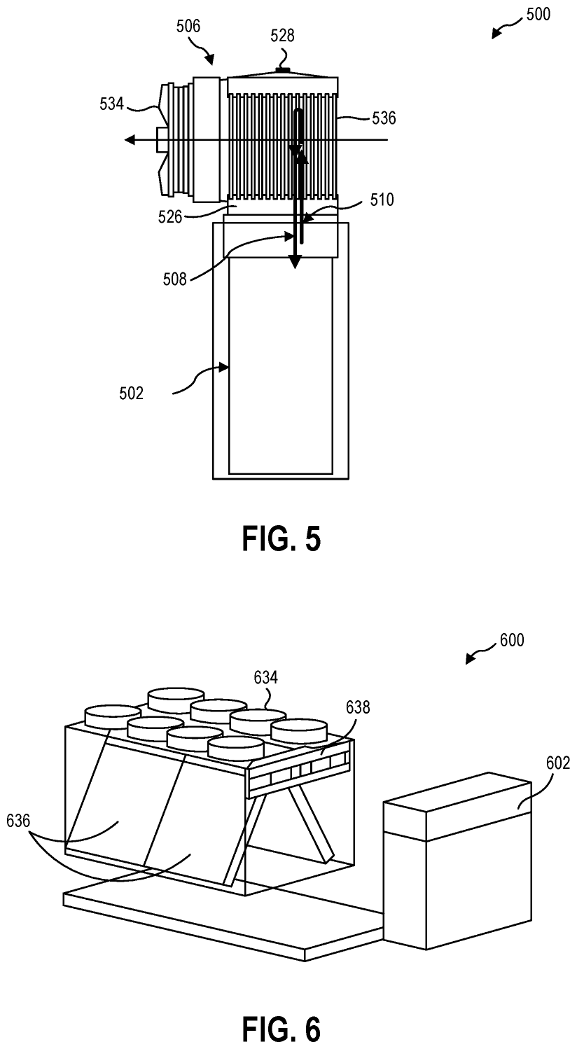

In some embodiments, the condenser and fluid conduits are modular from the immersion tank of the immersion cooling system. FIG. 5 is a side cross-sectional view of an embodiment of a top-condenser immersion cooling system 500 where the condenser 506 and return lines 518, 520 are self-contained in a top-mounted assembly integrated in a lid of the immersion tank 502. In some embodiments, the immersion tank 502 may be separated from the condenser 506 and return lines assembly to allow ease of repair, maintenance, and modification based on the heat-generating components positioned therein. For example, if it is determined that additional cooling capacity is needed to efficiently cool heat-generating components positioned in the immersion tank 502, the air-cooled condenser 506 and return lines assembly can be easily exchanged for a different condenser assembly with a larger heat exchanger, higher flow rate fans, etc.

In some embodiments, a top-condenser immersion cooling system 500 lacks a vapor return line and a liquid return line. The condenser 506 may include a heat exchanger 536 that receives vapor cooling fluid 510 rising from a top portion of the immersion tank 502. The heat exchanger 536 then extracts heat from the vapor cooling fluid 510 to condense the vapor cooling fluid 510 into liquid cooling fluid 508, which then falls back down into the immersion tank 502. In some embodiments, a condensate reservoir 526 is located below the heat exchanger 536 to catch and retain at least a portion of the liquid cooling fluid 508. In at least one example, the heat exchanger 536 includes a plurality of parallel fins or plates that may conduct heat away from the vapor cooling fluid 510 and condense the cooling fluid into droplets of liquid cooling fluid 508 on surfaces of the heat exchanger 536. A bottom edge of the heat exchanger 536 may be angled to guide the droplets of liquid cooling fluid 508 toward the condensate reservoir 526 to prevent the liquid cooling fluid 508 from dripping back into the immersion tank 502 unregulated. A valve on the condensate reservoir 526 may then selectively return the liquid cooling fluid 508 to the immersion tank 502.

In some embodiments, the condenser 506 includes a vapor return line, but lacks a liquid return line. For example, the condenser 506 may include a vapor return line to allow sensors and/or pumps, as described in relation to FIG. 3, to be positioned in the condenser 506 before the heat exchanger 536. In some embodiments, the condenser 506 includes a liquid return line, but lacks a vapor return line. For example, the condenser 506 may include a liquid return line to allow sensors and/or pumps, as described in relation to FIG. 3, to be positioned in the condenser 506 after the heat exchanger 536. Additionally, a liquid return line may allow the heat exchanger 536 to provide liquid cooling fluid to the condensate reservoir 526 more reliably than simply dripping the droplets into the condensate reservoir 526.

In some embodiments, a top-mounted condenser may be unfeasible due to space considerations and/or limited heat exchanger size of a top-mounted configuration. A top-mounted manifold may allow an immersion cooling system according to the present disclosure to extract vapor cooling fluid from the top of the immersion tank, such as described in relation to FIG. 5, while allowing the larger heat exchanger(s) of a side-condenser configuration, such as that described in relation to FIG. 4.

FIG. 6 is a perspective exploded view of an embodiment of a multi-condenser immersion cooling system 600 with a top-mounted manifold 638. In some embodiments, the vapor return line, such as the vapor return line 418 of FIG. 4, may be a manifold 638 that is in fluid communication with a plurality of heat exchangers 636. The manifold 638 may allow for greater flow rates with a larger cross-sectional area through which the vapor cooling fluid may flow. The embodiment of an immersion cooling system 600 illustrated in FIG. 6 includes a plurality of heat exchangers 636 oriented at an angle to the direction of gravity to draw air across the heat exchangers 636 and out a top of the condenser 606 to exhaust the air through one or more fans 634. In some embodiments, the manifold 638 is made of or includes a thermally conductive material that allows the manifold 638 to cool and/or condense the vapor cooling fluid. The condensed liquid cooling fluid can subsequently flow downward past the heat exchangers and return to the immersion tank 602 via a liquid return line, a condensate reservoir, a liquid pump, or other components or structures described herein.

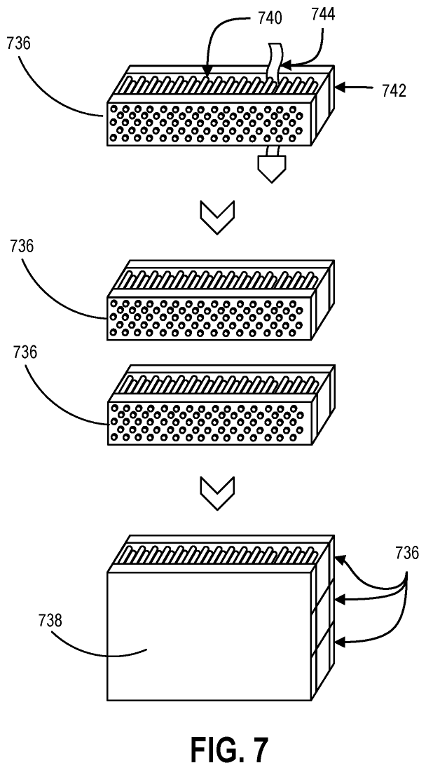

As described herein, some embodiments of a heat-exchanger according to the present disclosure include one or more elements for distributing, dispersing, and/or radiating heat. In at least one embodiment, the heat-exchanger includes heat pipes. Heat pipes may increase the rate of thermal transfer by moving the hot vapor through the heat exchanger efficiently and by increasing surface area of the heat-exchanger. FIG. 7 is a perspective view of a heat pipe heat-exchanger 736 that may be used in some embodiments of an air-cooled immersion cooling system.

In some embodiments, the heat pipe heat-exchanger 736 contains a plurality of heat pipes 740 that are supported by a frame 742. The vapor cooling fluid flow direction 744 may be directed vertically across (transverse to) the plurality of heat pipes 740 and allow the hot vapor cooling fluid to transfer thermal energy to larger surface area of the heat pipes. The heat pipes 740 can then conduct the thermal energy out to the ends of the heat pipes.

In some embodiments, the heat pipes 740 are arranged horizontally with the heat collection in the middle of the heat pipes 740 in an interior of the frame 742, and the rejection zone is positioned on the ends of the heat pipes 740 and/or outside of the frame 742. In some embodiments, two single ended heat pipes could be used with a heat pipe located on each end of the frame 742. Thermal energy may be collected in the center of the heat pipe heat-exchanger 736 causing a recondensing of the cooling fluid which will drip back into the tank.

As illustrated in FIG. 7, the passive cooling of the heat pipe heat-exchanger 736 allows for modularity of the immersion cooling system. In some embodiments, the heat pipe heat-exchangers 736 may be stacked to adjust the thermal capacity of the immersion cooling system based on anticipated or realized thermal loads. The more heat pipe heat-exchangers 736 through which the vapor cooling fluid is directed, the more heat pipes 740 and surface area thereof the vapor cooling fluid is exposed. As the heat pipe heat-exchangers 736 define the volume through which the vapor cooling fluid flows, there is no additional conduits, ducts, or pipes needed to expand the thermal capacity of the immersion cooling system.

In some embodiments, a stack of heat pipe heat-exchangers 736 may further increase thermal capacity by including a radiator or manifold 738 positioned on the ends of the heat pipes. In some embodiments, the radiator or manifold 738 includes fins located on the ends of the stack to further spread heat and reject heat into the ambient atmosphere.

A manifold 738 positioned on the ends of the assembly may permit gas flow between the heat pipes without exposing the gas to ambient atmosphere. In some embodiments, the manifold 738 contains a dry gas that limits corrosion of the system from ambient humidity. In some embodiments, the manifold 738 includes a higher thermal capacity gas than the ambient atmosphere. In some embodiments, the manifold 738 allows connecting flow of gas between the heat pipes of different heat pipe heat-exchangers 736 of the stack. In some embodiments, each heat pipe heat-exchanger 736 is self-contained allowing for many sizes to be designed through modular stacking of the heat pipe heat-exchangers 736. In at least one embodiment, a heat pipe heat-exchanger 736 similar to that illustrated in and/or described in relation to FIG. 7 may be arranged in a multi-condenser immersion cooling system with a top-mounted manifold such as that described in relation to FIG. 6.

### INDUSTRIAL APPLICABILITY

The present disclosure relates generally to systems and methods for thermal management of electronic devices or other heat-generating components. Immersion chambers surround the heat-generating components in a liquid cooling fluid, which conducts heat from the heat-generating components to cool the heat-generating components. As the cooling fluid absorbs heat from the heat-generating components, the temperature of the cooling fluid increases and the cooling fluid may vaporize, introducing vapor into the liquid of the cooling fluid.

An immersion cooling system according to the present disclosure includes a chamber with a cooling fluid positioned therein. The cooling fluid transitions between a liquid phase and a vapor phase to remove heat from hot or heat-generating components in the chamber. The liquid phase more efficiency receives heat from the components and, upon transition to the vapor phase, the cooling fluid can be cooled and condensed to extract the heat from the cooling fluid before the cooling fluid is returned to the liquid immersion bath at a lower temperature.

In some embodiments, the immersion bath of the liquid cooling fluid has a plurality of heat-generating components positioned in the liquid cooling fluid. The liquid cooling fluid surrounds the heat-generating components and other objects or parts attached to the heat-generating components. In some embodiments, the heat-generating components are positioned in the liquid cooling fluid on one or more supports. The support may support one or more heat-generating components in the liquid cooling fluid and allow the cooling fluid to move around the heat-generating components. In some embodiments, the support is thermally conductive to conduct heat from the heat-generating components. The support(s) may increase the effective surface area from which the cooling fluid may remove heat through convective cooling. In some embodiments, one or more of the heat-generating components includes a heat sink or other device attached to the heat-generating component to conduct away thermal energy and effectively increase the surface area of the heat-generating component.

As described, conversion of the liquid cooling fluid to a vapor phase requires the input of thermal energy to overcome the latent heat of vaporization and may be an effective mechanism to increase the thermal capacity of the cooling fluid and remove heat from the heat-generating components. Because the vapor rises in the liquid cooling fluid, the vapor phase can be extracted from the chamber in an upper vapor region of the chamber. A condenser cools part of the vapor of the cooling fluid back into a liquid phase, removing thermal energy from the system and reintroducing the cooling fluid into the immersion bath of the liquid cooling fluid. The condenser radiates or otherwise dumps the thermal energy from the cooling fluid into the ambient environment or into a conduit to carry the thermal energy away from the cooling system.

In conventional immersion cooling systems, the condenser is integrated into the boiler tank and/or the chamber to efficiency remove the thermal energy from the cooling fluid. In some embodiments according to the present disclosure, a system for thermal management of computing devices allows a plurality of boiler tanks and/or chambers to be connected to and in fluid communication with an external condenser. In some embodiments, an immersion cooling system includes a vapor return line and a liquid return line that connect the boiler tank to the condenser and allow vapor cooling fluid to enter the condenser from the boiler tank and/or chamber and allow liquid cooling fluid to return to the boiler tank and/or chambers. In some embodiments, a plurality of boiler tanks is connected to a shared vapor return line and/or shared liquid return line, which are in turn connected to a shared condenser, providing redundancy and scalability in the immersion capacity of the cooling system. In some embodiments, the vapor return line and liquid return line are connected to a plurality of condensers, providing redundancy and scalability in the condensing capacity of the cooling system.

In some embodiments, the cooling fluid receives heat in a cooling volume of cooling fluid immediately surrounding the heat-generating components. The cooling volume is the region of the cooling fluid (including both liquid and vapor phases) that is immediately surrounding the heat-generating components and is responsible for the convective cooling of the heat-generating components. In some embodiments, the cooling volume is the volume of cooling fluid within 5 millimeters (mm) of the heat-generating components. In some embodiments, the cooling volume is the volume of cooling fluid within 5 mm of the vertical stacks (supports and heat-generating components). In some embodiments, the cooling volume is defined by a vertical cylinder around each of the vertical stacks where no portion of the cylinder is within 5 mm of the heat-generating components.

The cooling fluid has a boiling temperature below a critical temperature at which the heat-generating components experience thermal damage. For example, the heat-generating components may be computing components that experience damage above 100° Celsius (C). In some embodiments, the boiling temperature of the cooling fluid is less than a critical temperature of the heat-generating components. In some embodiments, the boiling temperature of the cooling fluid is less about 90° C. In some embodiments, the boiling temperature of the cooling fluid is less about 80° C. In some embodiments, the boiling temperature of the cooling fluid is less about 70° C. In some embodiments, the boiling temperature of the cooling fluid is less about 60° C. In some embodiments, the boiling temperature of the cooling fluid is at least about 35° C. In some embodiments, the cooling fluid includes water. In some embodiments, the cooling fluid includes glycol. In some embodiments, the cooling fluid includes a combination of water and glycol. In some embodiments, the cooling fluid is an aqueous solution. In some embodiments, the cooling fluid is an electronic liquid, such as FC-72 available from 3M, or similar non-conductive fluids. In some embodiments, the heat-generating components, supports, or other elements of the immersion cooling system positioned in the cooling fluid have nucleation sites on a surface thereof that promote the nucleation of vapor bubbles of the cooling fluid at or below the boiling temperature of the cooling fluid.

In embodiments of immersion cooling systems with heat-generating components including computing components, similar computing components can be aggregated into stacks or series. For example, a first series of heat-generating components may be graphical processing units (GPUs) and a second series of heat-generating components may be central processing units (CPUs). In other examples, a first immersion cooling system houses GPUs and a second immersion cooling system houses CPUs.

In some embodiments, similar computing components can be aggregated into individual boiler tanks. For example, a first boiler tank may contain graphical processing units (GPUs) and a second boiler tank may contain central processing units (CPUs).

In some embodiments, an immersion tank defines an immersion chamber connected to an air-cooled condenser. The air-cooled condenser is connected to the immersion chamber by a vapor return line and a liquid return line. In some embodiments, a vapor pump is positioned in-line with the vapor return line. In some embodiments, a liquid pump is positioned in-line with the liquid return line. In some embodiments, the immersion cooling system includes only one of the vapor pump or liquid pump. For example, in a system with only a liquid pump, the condensation of the vapor cooling fluid in a liquid cooling fluid in the condenser creates a low pressure region at or near the condenser, which draws vapor cooling fluid through the vapor return line from the immersion chamber. In another example, in a system with only a vapor pump can create a region of high pressure at or near the condenser that forces liquid cooling fluid through the liquid return line.

In some embodiments, the liquid return line includes a condensate reservoir, which allows the liquid cooling fluid condensed in the condenser to be stored. The liquid cooling fluid can be selectively released to the immersion chamber via a valve in or after the condensate reservoir in the liquid return line.

When working on the immersion cooling system, such as installing, uninstalling, or repairing the immersion cooling system, as well as installing, uninstalling, or repairing heat-generating components in the immersion cooling system, non-condensable gases may be introduced into the system. It should be understood that a non-condensable gas, as described herein, includes any gaseous element or compound that is not condensable into a liquid phase by the condenser. For example, while the cooling fluid is condensable by the condenser during normal operational conditions, binary oxygen (O₂) is not. Conversely, while O₂ is condensable into a liquid phase at extremely low temperatures, such condensation is beyond the capability or intent of condensers according to the present disclosure, and O₂ is an example of a non-condensable gas. Other common non-condensable gases that may be introduced into the system include nitrogen and carbon dioxide. Non-condensable gases do not experience a phase change as they move through the immersion cooling system cycle. Therefore, the non-condensable gases do not allow for the same level of thermal energy transport as the cooling fluid moving between liquid and vapor phases, and the non-condensable gases can compromise the thermal management capacity of the immersion cooling system.

Non-condensable gases will pass through the condenser and may enter the liquid return line. Before the non-condensable gases can enter the immersion tank through the liquid return line, the non-condensable gases may be filtered from the liquid return line and vented through a vent. In some embodiments, the non-condensable gases are vented to atmosphere. In some embodiments, the non-condensable gases may be vented to another pipe or conduit to be collected. In some embodiments, the non-condensable gases vent is located before the condensate reservoir. In some embodiments, the non-condensable gases vent is located after the condensate reservoir. In some embodiments, the non-condensable gases vent is integrated into the condensate reservoir allowing the non-condensable gases to be vented from the condensate reservoir. For example, the condensate reservoir may have an outlet located at or near a bottom of the condensate reservoir that allow liquid cooling fluid to flow into the liquid return line, and the condensate reservoir may have a non-condensable gases vent located at or near a top of the condensate reservoir such that only gaseous material can exit through the vent. The density of the liquid condensate (e.g., the liquid cooling fluid) will separate the material in the condensate reservoir and allow the liquid cooling fluid to continue returning to the immersion tank.

Immersion cooling systems according to the present disclosure may include a variety of sensors to monitor the flow rate, pressure, temperature, density, or other properties and/or parameters of the immersion cooling system and/or cooling fluid. For example, sensors may be positioned at or in the immersion tank, the vapor return line, the liquid return line, the condenser, the condensate reservoir, other components of the immersion cooling system, or combinations thereof. In some embodiments, the immersion cooling system includes a plurality of at least one type of sensor to monitor changes to that property within the immersion cooling system. For example, an immersion cooling system according to the present disclosure may include temperature sensors at a plurality of location in or on the immersion cooling system to monitor temperature gradients and cooling efficiency in the immersion cooling system.

In some embodiments of immersion cooling systems, an immersion cooling system includes temperature and pressure sensors that measure a change in temperature and pressure between the vapor return line and the liquid return line. The immersion cooling system can use a first temperature and pressure sensor positioned on the vapor return line proximate the immersion tank to measure the temperature and pressure of the heated vapor cooling fluid exiting the immersion tank. The immersion cooling system can use a second temperature and pressure sensor positioned on the liquid return line proximate the immersion tank to measure the temperature and pressure of the liquid cooling fluid returning to the immersion tank. The differences between the two temperature and pressure sensors can provide a gradient that indicates the cooling efficiency of the condenser.

In some embodiments, an immersion cooling system includes one or more flow rate sensors. The flow rate sensors can monitor the rate of transport of the cooling fluid through the vapor return line and/or the liquid return line. It should be understood that the flow rate of the liquid cooling fluid in the liquid return line is lower than the flow rate of the vapor cooling fluid in the vapor return line when the immersion cooling system in a steady state, as the vapor cooling fluid is less dense than the liquid cooling fluid. In some embodiments, the immersion cooling system includes a flow rate sensor on the liquid return line, and flow rates measured by the flow rate sensor may be used to adjust a valve on the condensate reservoir and change the flow rate.

Some embodiments of a condenser according to the present embodiment are air cooled condensers that dissipate heat from the cooling fluid to the surrounding air. An air-cooled condenser is lower maintenance and more reliable than a liquid-cooled condenser. The air-cooled condenser includes a thermally conductive material that transfers heat from the cooling fluid to air passing over a heat exchanger of the condenser. In some embodiments, the heat exchanger includes one or more features or structures to increase surface area of the heat exchanger. For example, the heat exchanger may include a plurality of fins or columns that receive heat from the cooling fluid and conduct the heat to the air through convective heat transfer. The fins may be positioned substantially parallel to one another to allow airflow through the spaces between the fins. In some examples, the heat exchanger may include a heat spreader that increases the surface area exposed to the air. In some examples, the heat spreader is integrated with the fins or columns. In some examples, the heat exchanger includes a vapor chamber or heat pipe(s) to efficiently move heat across a large surface area.

In some embodiments, a condenser includes active cooling, such as a fan or blower to force air past the heat exchanger. The fan may be an axial fan, a centrifugal blower, or a mixed flow fan. In some embodiments, the fan is an electric fan powered by an external power source. In some embodiments, the fan is a thermoelectric fan that generates power from a temperature gradient, such as between the hot vapor cooling fluid and the surrounding air. A thermoelectric fan may flow air faster when the temperature gradient is larger, providing an adaptive and self-powering fan.

The condenser may include a plurality of fans to provide redundancy to the condenser. In some embodiments, at least two of the plurality of fans are the same, such that the second fan can replace the functionality and provide a backup to the first fan. In some embodiments, the condenser includes at least two different fans (e.g., an axial fan and a centrifugal blower or axial fans of different sizes) that provide efficient airflow at different flow rates. The condenser can operate one or both of the two different fans based on the properties measured by the sensors (such as the temperature and pressure sensors and the flow rate sensor).

The present disclosure relates to systems and methods for cooling heat-generating components of a computer or computing device according to at least the examples provided in the sections below:

(A1) In some embodiments, an immersion cooling system according to the present disclosure includes an immersion tank that defines an immersion chamber therein. The immersion chamber contains a cooling fluid. An air-cooled condenser is in fluid communication with the immersion chamber to cool the cooling fluid.

(A2) In some embodiments, the system of (A1) includes a vapor return line (such as the vapor return line 318 of FIG. 3) to convey a vapor phase of the cooling fluid from the immersion chamber to the condenser.

(A3) In some embodiments, the system of (A1) or (A2) includes a liquid return line (such as the liquid return line 320 of FIG. 3) to convey a liquid phase of the cooling fluid from the condenser to the immersion chamber.

(A4) In some embodiments, the system of any of (A1) through (A3) includes a plurality of fins in the condenser to increase the surface area and improve heat dissipation of the condenser to the surrounding air.

(A5) In some embodiments, the system of any of (A1) through (A4) includes an air-cooled condenser with a vapor chamber or other heat spreader to efficiently spread the heat from the cooling fluid over a larger surface are in the condenser.

(A6) In some embodiments, the system of any of (A1) through (A5) includes at least one fan to flow ambient air through or over a surface of a heat exchanger of the condenser.

(A7) In some embodiments, the fan of (A6) is a thermoelectric fan. A thermoelectric fan uses a temperature gradient to power the fan, providing redundancy and/or adaptability of the cooling system and further reducing maintenance and monitoring requirements.

(A8) In some embodiments, the system of any of (A1) through (A7) includes a non-condensable gas vent. Non-condensable gases can take up volume in the immersion chamber and/or in the return lines and limit the volume available for the cooling fluid, which is more efficient at transporting heat through phase changes.

(A9) In some embodiments, the system of any of (A1) through (A8) includes a condensate reservoir in fluid communication with the air-cooled condenser to receive and store at least a portion of a liquid phase of the cooling fluid. In some embodiments, the condensate reservoir is positioned in the liquid return line.

(A10) In some embodiments, the system of (A9) includes a valve positioned after the condensate reservoir and configured to selectively allow the liquid phase of the cooling fluid to flow from the condensate reservoir to the immersion chamber.

(A11) In some embodiments, the system of any of (A1) through (A10) includes a first sensor to measure a first property of the cooling fluid at a first position.

(A12) In some embodiments, the system of (A11) includes a second sensor to measure the first property at a second position.

(A13) In some embodiments, the system of (A11) or (A12) includes a second sensor to measure a second property of the cooling fluid.

(A14) In some embodiments, the first property of any of (A11) through (A13) is a temperature of the cooling fluid.

(A15) In some embodiments, the first property of any of (A11) through (A13) is a flow rate of the cooling fluid.

(A16) In some embodiments, a thermal management system according to the present disclosure includes an immersion tank that defines an immersion chamber with a cooling fluid at least partially located in the immersion chamber. The immersion chamber is in fluid communication with an air-cooled condenser to cool the cooling fluid. The air-cooled condenser is connected to the immersion tank through a closed loop of a vapor return line connecting the immersion tank to the air-cooled condenser and configured to communicate a vapor phase of the cooling fluid to the air-cooled condenser from the immersion tank and a liquid return line connecting the air-cooled condenser to the immersion tank and configured to communicate a liquid phase of the cooling fluid to the immersion tank from the air-cooled condenser. The system further includes a condensate reservoir positioned in the liquid return line and configured to store at least a portion of the liquid phase of the cooling fluid.

(A17) In some embodiments, the air-cooled condenser of (A16) is a lid of the immersion tank. By integrating the air-cooled condenser into a lid of the immersion tank, the system is modular and different size and capacity condensers can be easily paired with immersion tanks of different sizes and capacities.

(A18) In some embodiments, a heat exchanger of the air-cooled condenser of (A16) is oriented relative to a direction of gravity to allow the liquid phase of the cooling fluid to exit the heat exchanger.

(A19) In some embodiments, the vapor return line of (A16) through (A18) includes or is a manifold.

(A20) In some embodiments, a thermal management system includes an immersion tank that defines an immersion chamber with a cooling fluid at least partially located in the immersion chamber. The immersion chamber is in fluid communication with an air-cooled condenser to cool the cooling fluid. The air-cooled condenser includes a heat exchanger and a fan to move air past the heat exchanger. The heat exchanger is connected to the immersion tank through a closed loop of a vapor return line connecting the immersion tank to the air-cooled condenser and configured to communicate a vapor phase of the cooling fluid to the air-cooled condenser from the immersion tank and a liquid return line connecting the air-cooled condenser to the immersion tank and configured to communicate a liquid phase of the cooling fluid to the immersion tank from the air-cooled condenser. The system further includes a condensate reservoir positioned in the liquid return line and configured to store at least a portion of the liquid phase of the cooling fluid and at least one sensor positioned on the vapor return line or the liquid return line to measure a property of the cooling fluid.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A thermal management system comprising:
an immersion tank defining an immersion chamber;
a cooling fluid at least partially located in the immersion chamber; and
an air-cooled condenser in fluid communication with the immersion chamber to cool the cooling fluid.

2. The thermal management system of claim 1, further comprising a vapor return line connecting the immersion tank to the air-cooled condenser and configured to communicate a vapor phase of the cooling fluid to the air-cooled condenser from the immersion tank.

3. The thermal management system of claim 1, further comprising a liquid return line connecting the air-cooled condenser to the immersion tank and configured to communicate a liquid phase of the cooling fluid to the immersion tank from the air-cooled condenser.

4. The thermal management system of claim 1, wherein the air-cooled condenser includes a plurality of fins.

5. The thermal management system of claim 1, wherein the air-cooled condenser includes a vapor chamber.

6. The thermal management system of claim 1, wherein the air-cooled condenser includes at least one fan to flow ambient air through or over a surface of a heat exchanger of the air-cooled condenser.

7. The thermal management system of claim 1, wherein the air-cooled condenser includes a plurality of heat pipes.

8. The thermal management system of claim 1, wherein the air-cooled condenser includes a non-condensable gas vent.

9. The thermal management system of claim 1, further comprising a condensate reservoir in fluid communication with the air-cooled condenser to receive and store at least a portion of a liquid phase of the cooling fluid.

10. The thermal management system of claim 9, further comprising a valve positioned after the condensate reservoir and configured to selectively allow the liquid phase of the cooling fluid to flow from the condensate reservoir to the immersion chamber.

11. The thermal management system of claim 1, further comprising a first sensor to measure a first property of the cooling fluid at a first position.

12. The thermal management system of claim 11, further comprising a second sensor to measure the first property at a second position.

13. The thermal management system of claim 11, further comprising a second sensor to measure a second property of the cooling fluid.

14. The thermal management system of claim 11, wherein the first property is a temperature of the cooling fluid.

15. The thermal management system of claim 11, wherein the first property is a flow rate of the cooling fluid.

16. A thermal management system comprising:
an immersion tank defining an immersion chamber;
a cooling fluid at least partially located in the immersion chamber;
an air-cooled condenser in fluid communication with the immersion chamber to cool the cooling fluid;
a vapor return line connecting the immersion tank to the air-cooled condenser and configured to communicate a vapor phase of the cooling fluid to the air-cooled condenser from the immersion tank;
a liquid return line connecting the air-cooled condenser to the immersion tank and configured to communicate a liquid phase of the cooling fluid to the immersion tank from the air-cooled condenser; and
a condensate reservoir positioned in the liquid return line and configured to store at least a portion of the liquid phase of the cooling fluid.

17. The thermal management system of claim 16, wherein the air-cooled condenser is a lid of the immersion tank.

18. The thermal management system of claim 16, wherein a heat exchanger of the air-cooled condenser is oriented relative to a direction of gravity to allow the liquid phase of the cooling fluid to exit the heat exchanger.

19. The thermal management system of claim 16 further comprising:
a second immersion tank wherein:
the second immersion tank is in fluid communication with the vapor return line and configured to communicate a vapor phase of the cooling fluid to the air-cooled condenser from the second immersion tank, and
the second immersion tank is in fluid communication with the liquid return line and configured to communicate a liquid phase of the cooling fluid to the second immersion tank from the air-cooled condenser.

20. A thermal management system comprising:
an immersion tank defining an immersion chamber;
a cooling fluid at least partially located in the immersion chamber;
an air-cooled condenser in fluid communication with the immersion chamber to cool the cooling fluid, wherein the air-cooled condenser includes:
a heat exchanger, and
a fan to move air past the heat exchanger;
a vapor return line connecting the immersion tank to the air-cooled condenser and configured to communicate a vapor phase of the cooling fluid to the air-cooled condenser from the immersion tank;
a liquid return line connecting the air-cooled condenser to the immersion tank and configured to communicate a liquid phase of the cooling fluid to the immersion tank from the air-cooled condenser;
a condensate reservoir positioned in the liquid return line and configured to store at least a portion of the liquid phase of the cooling fluid; and
at least one sensor positioned on the vapor return line or the liquid return line to measure a property of the cooling fluid.
